(19) United States
(12) Patent Application Publication
(10) Pub. No.: US 2008/0044584 A1
(43) Pub. Date: Feb. 21, 2008

(54) Device and a Method for Stabilizing a Metallic Object

(75) Inventors: Jan-Erik Eriksson, Vasteras (SE); Conny Svahn, Vasteras (SE); Mats Molander, Vasteras (SE); Carl-Fredrik Lindberg, Vasteras (SE); Peter Lofgren, Vasteras (SE); Stefan Israelsson Tampe, Vasteras (SE); Bengt Rydholm, Vasteras (SE)

Correspondence Address: VENABLE LLP, P.O. BOX 34385, WASHINGTON, DC, 20043-9998, US

(73) Assignee: ABB AB, Vasteras (SE)

(21) Appl. No.: 11/632,312

(22) PCT Filed: Jun. 23, 2005
(86) PCT No.: PCT/SE05/01005

§ 371 Date: Jan. 12, 2007

(30) Foreign Application Priority Data
Jul. 13, 2004 (SE) 0401860-2

(51) Int. Cl. C23C 2/20; B05C 3/12; C23C 16/52; B05D 1/18

(52) U.S. Cl. 427/430.1; 118/673; 118/419; 118/500; 118/63; 427/8

(57) ABSTRACT

A device and a method for stabilizing an elongated metallic strip of a magnetic material when coating the strip with a metallic layer. The strip is transported from the bath in a direction of transport along a predetermined transport path. A wiping device for wiping off superfluous molten metal from the strip applies an air flow in a line across the strip, where the wiping device includes at least one pair of air-knives arranged with one air-knife on each side of the strip. An electromagnetic stabilizing device stabilizes the position of the strip with respect to the predetermined transport path. A sensor detects the position of the strip in relation to the predetermined transport path.

### TECHNICAL FIELD

The present invention relates to a device for stabilizing an elongated metallic object of magnetic material when coating the object with a layer of metal by continuously transporting the object through a bath of molten metal. The metallic object is intended to be transported from said arrangement in a direction of transport along a predetermined transport path. The device comprises a wiping device for wiping off superfluous molten metal from the object by applying an air flow to the metallic object and where the wiping device comprises at least one first pair of air-knives comprising one air-knife on each side of the object. The device also comprises an electromagnetic stabilizing device which is arranged to stabilize the position of the object with respect to the predetermined transport path and which comprises at least one first pair of electromagnetic stabilizing members on each side of the plane.

The invention also relates to a method for stabilizing an elongated metallic object that is coated with a layer of molten metal. The coating is applied by continuously transporting the object through a bath of molten metal.

Such a device is especially advantageous when continuously galvanizing a metal strip. The present invention will here after be described with reference to such an application. However, it should be noted that the invention is also applicable to galvanization of other metal objects, such as wires, rods, tubes or other elongated elements.

### BACKGROUND ART

During continuous galvanization of a metallic strip, for example a steel strip, the steel strip continuously passes through a bath that contains molten metal, usually zinc. In the bath, the strip usually passes below an immersed roller and thereafter moves upwards through stabilizing and correcting rollers. The strip leaves the bath and is conveyed through a set of gas-knives, which blow away superfluous zinc from the strip and back to the bath, and in this way the thickness of the coating is controlled. The gas that is blown out with the knives may be air, nitrogen, steam or inert gas, but air and nitrogen are used most often. The strip is then conveyed without support until the coating has been cooled down and solidified. The coated steel strip is then led or directed via an upper roller to an arrangement for cutting the strip into separate strip elements or for winding the strip onto a roller. Normally, the strip moves in a vertical direction away from the immersed roller through the correcting and stabilizing rollers and the gas-knives to the upper roller.

When steel strip is galvanized, an even and thin thickness of the coating is aimed at. One common method is to measure the mass of the coating after the strip has passed through the upper roller. This reading is utilized for controlling the gas-knives and hence controlling the thickness of the coating. The gas-knives are usually arranged suspended from a beam that is movably arranged in the vertical direction and in a direction towards the strip. The gas-knives may also be angled such that the angle at which the gas hits the coating on the strip may be changed. Due to the geometry of the steel strip, the length the strip has to run without support, its speed and the blowing effect of the gas-knives, however, the steel strip will move in a direction that is essentially perpendicular to its direction of transport.

Certain measures, such as the use of correcting and stabilizing rollers, a precise control of the gas flow from the gas-knives, and an adjustment of the speed of the steel strip and/or an adjustment of the distance over which the strip has to run without support, may be taken for the purpose of reducing these transversal movements. If they are not reduced, these transversal movements will considerably disturb the exact wiping of the gas-knives, which results in an uneven thickness of the coating.

In the Japanese publication with publication number JP 09-202955, it is shown how the vibrations in a metallic strip are reduced with the aid of rolls that stabilize and tension the strip after having passed through the gas-knives. The position of the strip in relation to its direction of transport in a plane is measured with a sensor, from where information is passed on to a computer that carries out a vibration analysis based on the values obtained and, together with information about the speed of the strip, calculates the optimum tensioning of the strip to control the vibrations in the strip.

It is also known from the published document JP 3173755 to arrange stabilizing devices in a device for galvanizing a metallic strip in order to reduce the vibrations of the strip. These stabilizing devices comprise wiping devices arranged at, and in contact with, the corners of the respective edge of the strip to fix the edges in the desired position and an electromagnet arranged in a region opposite to the width of the strip, on opposite sides of the strip and between the respective guide device, to reduce the vibrations of the strip. The stabilizing device is placed downstream of the gas-knives.

One problem with known devices is that they do not provide sufficient stabilization of the strip. There is a need to place the air-knives closer to the strip to make the wiping more efficient and to obtain a higher quality of the layer. With the stabilizers of today, this is not possible since space must be provided for the vibrations of the plate between the air-knives, which results in the layer thickness becoming larger than what is desired. A thick layer results in a more expensive product than if the layer could have been made thinner, and also causes surface defects, such as uneven coating.

### SUMMARY OF THE INVENTION

The object of the invention is to provide a device for stabilizing and reducing vibrations in an elongated metallic object of magnetic material, such as a metallic strip, in connection with air wiping of superfluous molten metal from the strip.

This object is achieved according to the invention by a device according to the features described in the characterizing portion of the independent claim 1.

This object is further achieved by a device comprising a wiping device for wiping off superfluous molten metal from the strip. The strip is continuously transported through an arrangement for applying molten metal to the strip, for example a bath of molten metal. The strip is intended to be transported from the bath of molten metal in a direction of transport along a predetermined transport path (x). By applying an air flow in a line across the strip with the layer of molten metal, wiping of superfluous molten metal is achieved. The air flow is generated in a wiping device comprising at least one first pair of air-knives with one air-knife on each side of the strip. The device comprises a sensor that is arranged to detect the deviation of the strip from the predetermined transport path (x) in a region adjoining the line where the air flow from the air-knives hits the strip. Information about the deviation of the strip is then passed to control equipment for controlling an electromagnetic stabilizing device. The stabilizing device, which is arranged to stabilize the position of the object with respect to the predetermined transport path, comprises at least one first pair of electromagnetic stabilizing members arranged adjacent to the air-knives and on each side of the strip. Since the air-knives and the electromagnetic stabilizing members are arranged adjacent to each other to reduce the movement of the object perpendicular to the direction of transport, an optimal damping of the vibrations is achieved at the region between the air-knives.

Advantageous developments of the invention will be clear from the following description and from the dependent device claims 2-11.

According to an advantageous embodiment, the position of the plate is detected in close proximity to the disturbance generated by the air flow from the air-knives on the plate. Preferably, the disturbance is detected within an interval of 0-500 mm from the disturbance, that is, the location where the air flow hits the plate, most preferably within an interval of 0-200 mm from the disturbance on the plate. In those cases where the sensors are inclined, it is possible to measure in or in immediate proximity to the line where the air flow hits the coating on the strip.

According to a preferred embodiment, the device comprises a sensor arranged to sense the value of a parameter that depends on the position of the strip with respect to the predetermined transport path, whereby the stabilizing device is arranged to apply a magnetic force to the strip that responds to the sensed value and that is directed across the transport direction and across the predetermined transport path. The sensed value of a parameter is processed in a signal-processing device and controls the current that flows to the coils in the electromagnetic stabilizing device. The sensor is suitably movably arranged in a direction towards the strip such that the position of the sensor is adapted to the thickness of the strip. The sensor is, for example, an inductive transducer or a laser transducer to measure a distance. One advantage of a laser transducer is that it may be placed at a larger distance from the strip than the inductive transducer.

According to another embodiment of the invention, each stabilizing member comprises at least two stabilizing coils, wherein the two stabilizing coils are movably arranged in the extent of the metal strip across the transport direction and in the predetermined transport path. By arranging the two stabilizing coils to be movable, an optimum quality of the coating is obtained, irrespective of bandwidth.

According to yet another embodiment of the invention, each stabilizing member comprises at least three stabilizing coils, wherein at least two of the coils, preferably the coils arranged at the edges of the metal strip, are movable in the extent of the metal strip across the transport direction. By arranging at least two of the coils to be movable, a stabilization is obtained that is adapted to the relevant bandwidth.

According to still another embodiment, the air-knife is arranged at a beam for controlling the location of the air-knife, and the stabilizing device is arranged in the beam for achieving as efficient a stabilization of the strip as possible. The air-knife is preferably movably arranged at the beam via a suspension device such that the angle of the air that hits the strip is controlled by angularly adjusting the air-knife.

According to still a further embodiment, the stabilizing device is secured outside the beam that holds the air-knife. This results in the stabilizer acting on the strip adjacent to the location where the disturbance from the air-knives on the strip arises.

According to yet a further embodiment, the stabilizer is arranged on a beam that is separated from the beam of the air-knife and that is arranged in close proximity to the beam of the air-knife. The beam with the stabilizer is movably arranged horizontally in a direction towards the strip and also in a direction vertically substantially parallel to the direction of movement of the strip. This means that the position of the stabilizer may be adjusted independently from the position of the air-knife.

The object of the invention is also achieved by means of a method according to the features described in the characterizing portion of the independent claim 12.

Preferred embodiments of the method are defined in the dependent method claims 13-15 and in the following paragraph. According to an additional embodiment of the invention, tensioning of the strip occurs before the stabilization of the strip begins. One of the at least two stabilizing members arranged on each side of the strip is configured to act on the strip with an active magnetic force that attracts the strip. This results in the strip being tensioned by allowing the strip to run a somewhat longer distance when being moved from its original position in the predetermined transport path to a new position closer to the stabilizing member with the active magnetic force. The active magnetic force is brought about by superimposing a constant current onto the current to the coil or the coils in one of the at least two stabilizing devices. The tensioning of the strip results in a more efficient stabilization on the strip.

One advantage of the invention is that by placing the stabilizing members quite close to the air-knives, the vibrations that arise just in front of the air-knives, and due to the influence of the air on the strip, are damped. Because the vibrations are efficiently damped, the nozzle of the air-knives may be placed closer to the strip and hence the efficient of the air-knife is increased. A more efficient air-knife means that more of the layer may be scraped off with the air-knife and a thinner layer be obtained. A thinner layer results in a reduction of the waviness of the surface and in a reduction of optical defects, for example so-called roses, on the coated surface.

Still another advantage is that a vibration node may be created right in front of the nozzle of the air-knife, which results in the strip standing still right in front of the air-knife.

### BRIEF DESCRIPTION OF THE DRAWINGS

The invention will be explained in greater detail by description of embodiments with reference to the accompanying drawings, wherein

FIG. 1 schematically shows an arrangement for applying a coating to a metal strip and a device for stabilizing the metal strip,

FIG. 2 shows the stabilizing device of FIG. 1, wherein the stabilizing device is movably arranged,

FIG. 3 shows the stabilizing device of FIG. 1 with an alternative location of the sensor,

FIG. 4 shows the stabilizing device of FIG. 1 with a laser transducer as a sensor,

FIG. 5 shows the stabilizing device of FIG. 1 according to an alternative embodiment, wherein the stabilizing device at least partly surrounds the air-knife,

FIG. 6 shows an alternative embodiment of the stabilizing device of FIG. 5,

FIG. 7 schematically shows an arrangement of the coils in a stabilizing device according to the invention, and

FIG. 8 schematically shows an alternative arrangement of the coils in a stabilizing device according to the invention.

### DESCRIPTION OF PREFERRED EMBODIMENTS

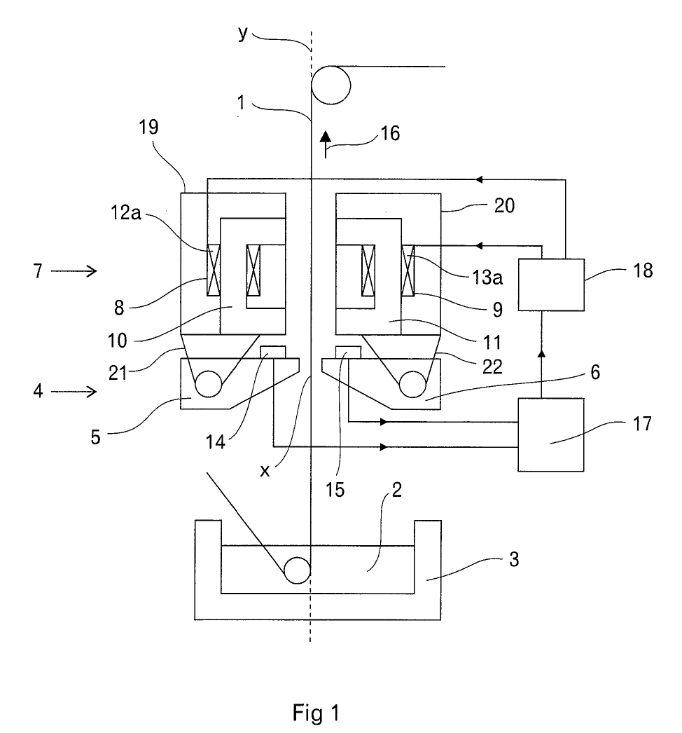

FIG. 1 shows a device for stabilizing an elongated metallic strip 1 when coating the strip with a layer by continuously transporting the strip through a bath 2 of molten metal in a container 3.

The device comprises a wiping device 4 for wiping off superfluous molten metal from the strip by applying an air flow to the metallic strip and wherein the wiping device comprises at least one first pair of air-knives 5, 6 comprising one air-knife on each side of the strip 1. The air-knife 5, 6 is arranged at a beam 19, 20 via a suspension device 21, 22, and because the beam is movably arranged in the vertical and horizontal directions, the location of the air-knife may be adjusted in relation to the position of the strip 1. The device also comprises an electromagnetic stabilizing device 7 that is arranged to stabilize the position of the strip with respect to a predetermined transport path x. The electromagnetic stabilizing device 7 comprises at least one first pair of electromagnetic stabilizing members 8, 9 arranged on each side of the plane x. The stabilizing members 8, 9 in FIG. 1 each comprise an iron core 10, 11 and two coils 12a-b, 13a-b each, only one coil 12a, 13a in each stabilizing member 8, 9 being visible in FIG. 1. One coil from each stabilizing member 8, 9 forms one pair of coils 12a, 13a that are electrically connected to each other and that are controlled together for stabilizing the strip. The stabilizing members 8, 9 in FIG. 1 are arranged at a specific distance from the predetermined transport path x. The stabilizing members 8, 9 are arranged in the beam 19, 20 to act near the line where the air-knife influences the strip and hence achieve as efficient a stabilization of the strip as possible. Between a roller immersed into the bath and an upper roller, arranged downstream of the stabilizing device 7, the predetermined transport path x extends substantially in a plane y.

On each side of the strip and on the air-knife 5, 6, a sensor 14, 15 is arranged to sense the position of the strip 1 in relation to the predetermined transport path x in a region that adjoins the line where the air flow from the air-knives 5, 6 hits the metallic layer on the strip 1. The line-shaped region extends over essentially the whole width of the strip. The stabilizing members 8, 9 are arranged adjacent to the air-knife 5, 6 and apply a magnetic force to the strip in dependence on the sensed position, and in a direction perpendicular to the strip 1.

The sensors 14, 15 are arranged to detect the value of the parameter that depends on the position of the strip with respect to the predetermined transport path x, whereby the stabilizing members 8, 9 apply a force to the strip 1 that responds to the detected value. The signal from the sensors 14, 15 are processed in a signal-processing device 17 and a control program in the converter 18 controls the current that flows to the stabilizing members 8, 9 for stabilizing the strip 1.

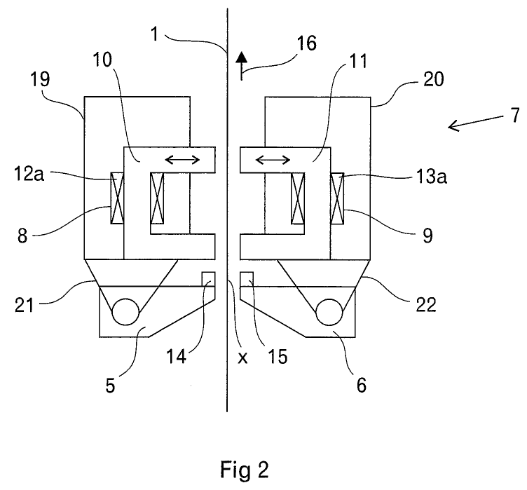

FIG. 2 shows the device according to FIG. 1, with the difference that the stabilizing members 8, 9, which are arranged in the beams 19, 20, are movably arranged in a direction towards the strip 1. The sensor 14, 15 is arranged on the air-knife 5, 6.

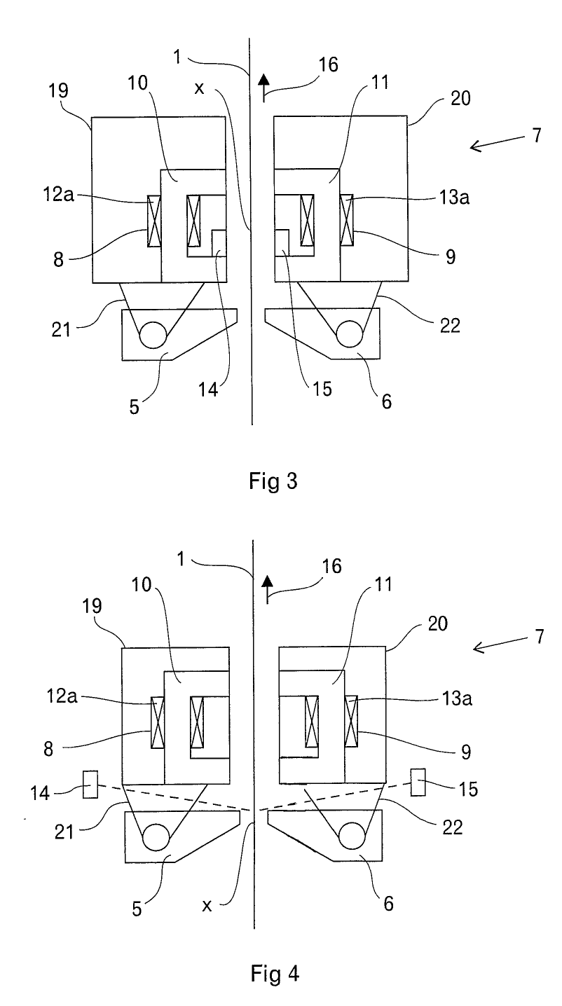

FIG. 3 shows the device according to FIG. 1, with the difference that the sensor 14, 15 is arranged in the stabilizing members 8, 9 which are arranged in the beam 19, 20.

FIG. 4 shows the device according to FIG. 1, with the difference that the sensor 14, 15 is arranged behind the stabilizing device 7 and the air-knives 5, 6, and that the sensor 14, 15 is a laser cutter for distance measuring. By locating the sensor 14, 15 at a distance from the strip 1, maintenance of the sensor is facilitated. The sensor 14, 15 is angled such that the measuring point lies in or immediately adjacent to the line where the air from the air-knife 5, 6 hits the strip 1.

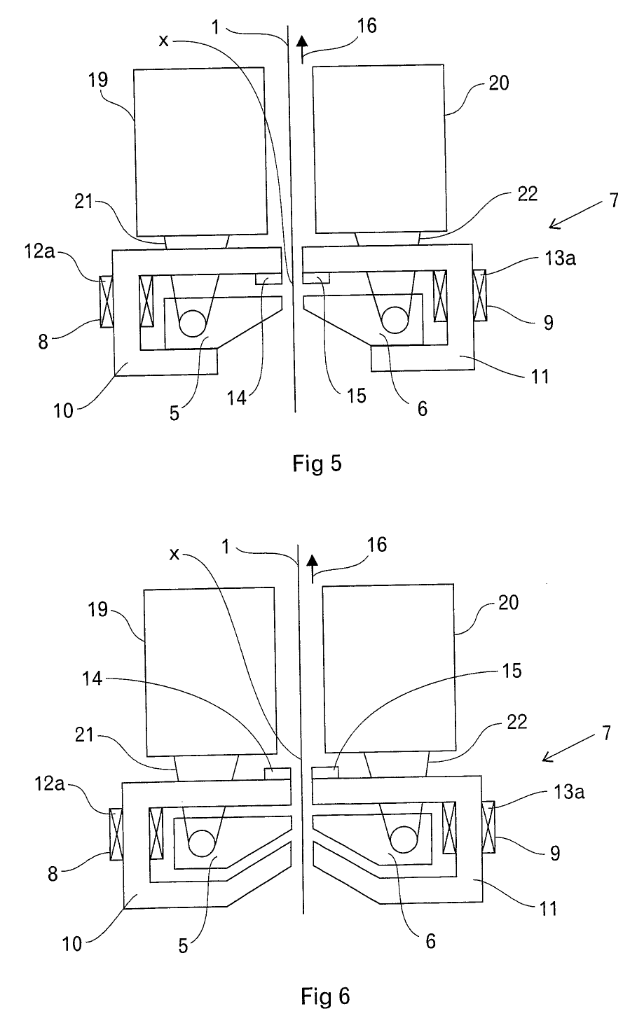

FIG. 5 shows an alternative embodiment of the invention, where the iron core 10, 11 of the stabilizing member at least partially surrounds the air-knife so as to form an opening for air that is generated by the air-knife for wiping off superfluous metal from the layer of molten metal. The sensor 14, 15 is arranged on the iron core 10,11.

FIG. 6 shows an alternative embodiment of the stabilizing device of FIG. 5, wherein the air-knife is fixedly connected to the stabilizing member 8, 9. The sensor 14, 15 is arranged between the iron core 10, 11 of the stabilizing member and the air-knife 5, 6.

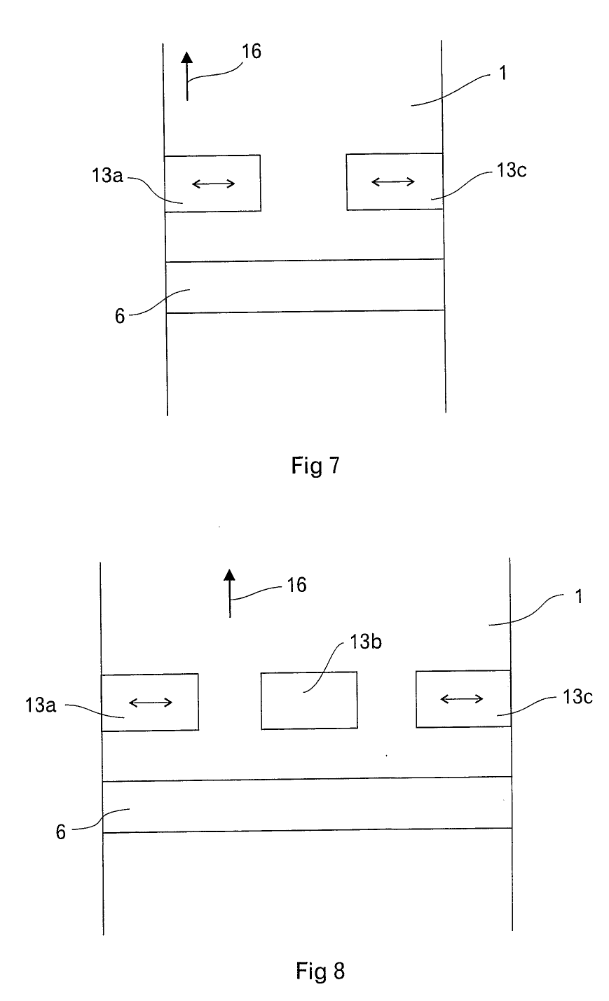

FIG. 7 shows a stabilizing device 4, wherein the stabilizing member 5, 6 comprises two coils 13a,c that are movable in the extent of the strip 1 across the transport direction 16. FIG. 8 shows an alternative embodiment of the stabilizing device of FIG. 7, wherein each stabilizing member 8, 9 comprises three coils 13a-c, of which at least two coils 13a,c are movable in the extent of the strip 1 across the transport direction 16. By arranging two coils 13a,c on each side of the centremost coil 13b to be movable, the stabilizing device may be adapted to the current width of the strip.

The invention is not limited to the embodiments shown but a person skilled in the art may, of course, modify it in a plurality of ways within the scope of the invention as defined by the claims. The strip may, for example, be transported in a horizontal direction.

1. A device for stabilizing an elongated metallic strip of magnetic material when coating the strip with a metallic layer by continuously transporting the strip through a bath of molten metal, wherein the strip is intended to be transported from the bath in a transport direction along a predetermined transport path, the device comprising:
a wiping device for wiping off superfluous molten metal from the strip by applying an air flow in a line across the strip, wherein the wiping device comprises at least one pair of air-knives arranged with one air-knife on each side of the strip,
an electromagnetic stabilizing device which is arranged to stabilize the position of the strip with respect to the predetermined transport path and which comprises at least one electromagnetic stabilizing member on each side of the strip, and
a sensor arranged to detect the position of the strip in relation to the predetermined transport path, wherein the sensor is configured to detect the position of the strip in relation to the predetermined transport path in a region adjoining the line where the air flow from the air-knives hits the strip, and wherein the electromagnetic stabilizing members are arranged adjacent to the air-knives and are arranged to apply a magnetic force to the strip in dependence on the measured position and in a direction substantially perpendicular to the predetermined transport path.

2. The device according to claim 1, wherein the sensor is arranged to detect the value of a parameter that depends on the position of the strip with respect to the predetermined transport path in a region that lies at a distance in the interval of 0-500 mm, from the line where the air flow from the air-knives hits the strip.

3. A The device according to claim 1, wherein each electromagnetic stabilizing member comprises two stabilizing coils.

4. The device according to claim 1, wherein each electromagnetic stabilizing member comprises three stabilizing coils.

5. The device according to claim 3, wherein at least two of the stabilizing coils in a stabilizing member are movably arranged along the width of the strip.

6. The device according to claim 1, wherein the sensor is an inductive transducer.

7. The device according to claim 1, wherein the sensor is a laser cutter for distance measuring.

8. The device according to claim 1, wherein the sensor is secured to the air-knife.

9. The device according to claim 1, wherein the air-knife is arranged at a beam, and wherein the sensor is located in the beam.

10. The device according to claim 1, wherein the air-knife is arranged at a beam, and wherein the stabilizing members are built into the beam.

11. The device according to claim 1, wherein the iron core of the stabilizing member surrounds the air-knife.

12. A method for stabilizing an elongated metallic strip of magnetic material when coating the strip with a metallic layer, wherein said layer is applied by continuously transporting the strip through a bath of molten metal, the method comprising:
transporting the metallic strip from the bath in a direction along a predetermined transport path,
wiping off superfluous molten metal from the strip by applying an air flow to the strip and in a line across the strip, wherein the air flow is generated by a wiping device comprising an air-knife on each side of the strip,
detecting with a sensor the position of the strip with respect to the position of the predetermined transport path in a region adjoining the line where the air flow from the air-knives hits the strip, and
stabilizing the position of the strip with respect to the predetermined transport path by applying a stabilizing magnetic force to the strip that responds to the position of the strip with respect to the predetermined transport path.

13. The method according to claim 12, wherein the stabilizing magnetic force is applied to the strip adjacent to the line where the air flow from the air-knives hits the metallic layer.

14. The method according to claim 12, wherein the detection of the position of the strip with the sensor generates a value of a parameter that controls the application and the magnitude of the stabilizing magnetic force.

15. The method according to claim 12, wherein tensioning of the strip is carried out before the stabilization of the strips begins, the tensioning being carried out by arranging one of the stabilizing members arranged on each side of the strip to act on the strip with an active magnetic force that pulls the strip towards the active stabilizing member.

16. Use of a device according to claim 1 for stabilizing a metallic elongated strip when coating the strip with a metallic layer.

17. The device according to claim 1, wherein the sensor is arranged to detect the value of a parameter that depends on the position of the strip with respect to the predetermined transport path in a region that lies at a distance in the interval of 0-200 mm from the line where the air flow from the air-knives hits the strip.
